(19) United States
(12) Patent Application Publication
(10) Pub. No.: US 2016/0146985 A1
(43) Pub. Date: May 26, 2016

(54) COLOR FILTER SUBSTRATE AND MANUFACTURING METHOD THEREOF, DISPLAY PANEL

(71) Applicants: BOE TECHNOLOGY GROUP CO., LTD., Beijing (CN); HEFEI XINSHENG OPTOELECTRONICS TECHNOLOGY CO., LTD., Hefei City (CN)

(72) Inventors: Bin LI, Beijing (CN); Sang Man YUK, Beijing (CN)

(21) Appl. No.: 14/801,157

(22) Filed: Jul. 16, 2015

(30) Foreign Application Priority Data
Nov. 25, 2014 (CN) 201410687131.1

(51) Int. Cl. G02B 5/20; G03F 7/00

(52) U.S. Cl. CPC G02B 5/201; G03F 7/0007

(57) ABSTRACT

There are provided a color filter substrate and a manufacturing method thereof, a display panel. The color filter substrate includes a base substrate, a black matrix and a color filter layer that are formed on the base substrate, wherein, the black matrix and the color filter layer are at least partially overlapped in a direction perpendicular to surface of the base substrate, and a thickness of a portion of the color filter substrate that overlaps with the black matrix is smaller than a thickness of a portion of the color filter substrate that does not overlap with the black matrix.

### TECHNICAL FIELD

Embodiments of the present invention relate to a color filter substrate and manufacturing method thereof, a display panel.

### BACKGROUND

FIG. 1 is a schematic plan illustrating a conventional color filter substrate, on which black matrices 14 are formed, and color filter layers of different colors 11, 12 and 13 are formed between the black matrices 14. In order to ensure that the color filter substrate will not suffer from light leakage, the color filter layer has a portion overlapping with the black matrices. FIG. 2 is a sectional contour plot of the color filter substrate illustrated in FIG. 1 in the direction of AA′; FIG. 3 is a sectional contour plot of the color filter substrate illustrated in FIG. 1 in the direction of BB′; and FIG. 4 is a schematically sectional view of the color filter substrate illustrated in FIG. 1 in the direction of BB′. Taking the color filter layer 13 as an example, as illustrated in FIGS. 2 to 4, the color filter layer 13 includes a portion that overlaps with the black matrices 14 and a portion that does not overlap with the black matrices 14.

In view of the fact that the color filter layer has a portion overlapping with the black matrices, as illustrated in FIG. 4, surface height H2 for a portion of the color filter layer 13 that overlaps with the black matrices 14 and surface height H1 for a portion of the color filter layer 13 that does not overlap with the black matrices 14 have a difference with each other. This affects flatness of the color filter substrate. Flatness of the color filter substrate may be improved by providing a planarizing layer on the color filter substrate, but as illustrated in FIG. 5, under the influence of surface height difference of a color filter layer, a distance c that the line of sight propagates in the color filter layer 13 at a viewing angle of −45°, differences between a distance b that the line of sight propagates in the color filter layer 13 at a viewing angle of 0°, and a distance a that the line of sight propagates in the color filter layer 13 at a viewing angle of 45° are bigger. This may cause the following problem: chromatic aberration of the color filter substrate at different viewing angles is larger. Eventually, the display effect of the display panel is affected.

### SUMMARY

According to an embodiment of the present invention, there is provided a color filter substrate, which includes a base substrate, a black matrix and a color filter layer that are formed on the base substrate, wherein, the black matrix and the color filter layer are at least partially overlapped in a direction perpendicular to surface of the base substrate, and a thickness of a portion of the color filter substrate that overlaps with the black matrix is smaller than a thickness of a portion of the color filter substrate that does not overlap with the black matrix.

According to another embodiment of the invention, there is provided a display panel, which includes the above color filter substrate.

According to still another embodiment of the invention, there is provided a manufacturing method of a color filter substrate, which includes: forming a layer of color resin on a substrate with a black matrix formed thereon; and performing exposure and development on the color resin, so as to form a pattern of a color filter layer, wherein, a thickness of the color filter layer that overlaps with the black matrix is smaller than a thickness of the color filter layer that does not overlap with the black matrix.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic plan illustrating an existing color filter substrate;

FIG. 2 is a sectional contour plot of the color filter substrate illustrated in FIG. 1 in the direction of AA′;

FIG. 3 is a sectional contour plot of the color filter substrate illustrated in FIG. 1 in the direction of BB′;

FIG. 4 is a schematically sectional view of the color filter substrate illustrated in FIG. 1 in the direction of BB′;

FIG. 5 is a schematic view illustrating a larger chromatic aberration of an existing color filter at different viewing angles;

FIG. 6 is a structurally schematic view illustrating a mask according to an embodiment of the invention;

FIGS. 7 to 8 are schematically sectional views illustrating a color filter substrate according to an embodiment of the invention;

FIGS. 9 to 10 are schematic views illustrating a reduced chromatic aberration at different viewing angles according to an embodiment of the invention.

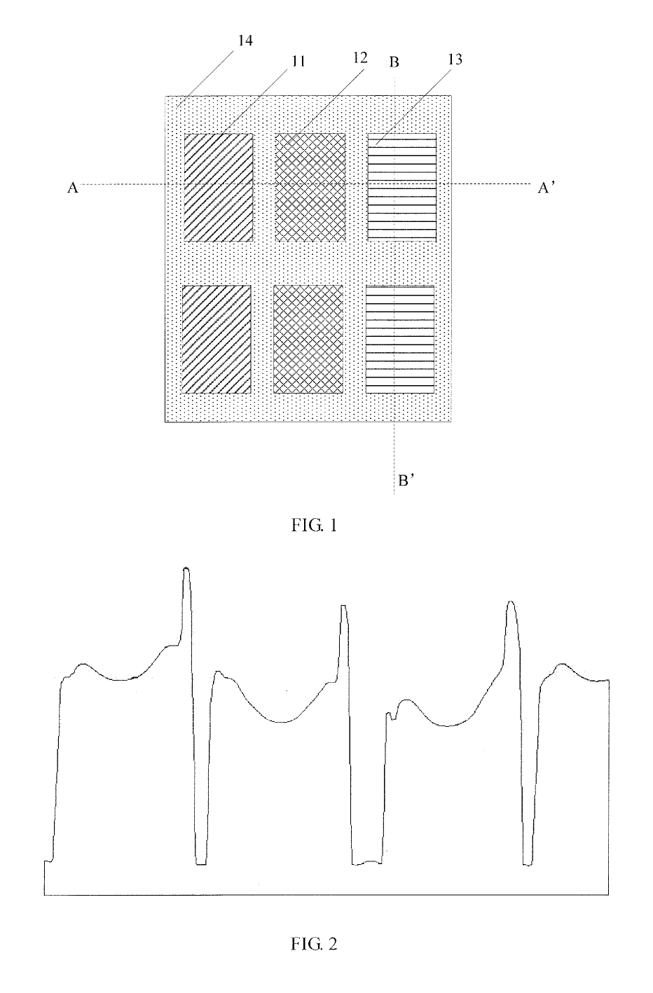

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

According to an embodiment of the invention, there is provided a color filter substrate, which includes a substrate (a base substrate), black matrices formed on the substrate, and a color filter layer formed between the black matrices, wherein, a thickness of a portion of the color filter layer that overlaps with the black matrices is smaller than a thickness of a portion of the color filter layer that does not overlap with the black matrices. For example, the black matrices and the color filter layer are at least partially overlapped in a direction perpendicular to a surface of the base substrate.

With the color filter substrate according to the embodiment, the difference in surface height of a color filter layer can be decreased. Not only flatness of the color filter substrate is improved, but also the problem that a color filter substrate has a larger chromatic aberration at different viewing angles can be ameliorated. Thus, the display effect of the display panel is promoted.

In some examples, at portions where the color filter layer and the black matrices overlap with each other, the black matrices are located under the color filter layer.

In some examples, the difference of surface height between a portion of the color filter layer that overlaps with the black matrices and a portion of the color filter layer that does not overlap with the black matrices is not greater than a preset threshold. In the event that the difference in surface height of the color filter layer is not greater than the preset threshold, flatness of a surface of the color filter substrate is better, and this enables chromatic aberration of the color filter substrate at different viewing angles to be relatively small. Size of the threshold can be adjusted according to display effect of the display panel. The surface height here refers to a distance from a lower surface (being a surface close to the substrate) where the black matrices and the color filter layer are coplanar to an upper surface of the color filter layer. That is, in a location where the color filter layer and the black matrices overlap with each other, the surface height is equal to a thickness sum of the color filter layer and the black matrices; and in a location where the color filter layer and the black matrices do not overlap with each other, the surface height is equal to the thickness of the color filter layer.

In some examples, the surface height for a portion of the color filter layer that overlaps with the black matrices is equal to the surface height for a portion of the color filter layer that does not overlap with the black matrices.

According to an embodiment of the invention, there is further provided a display panel, which includes the above color filter substrate.

According to an embodiment of the invention, there is further provided a mask, which is useful for forming a color filter layer on a color filter substrate, and which includes a semi-transmissive pattern corresponding to a portion of the color filter layer that overlaps with black matrices on a color filter substrate.

As for the color filter layer manufactured by using the mask according to the embodiment, the thickness of a portion of a color filter layer that overlaps with black matrices is smaller than the thickness of a portion of the color filter layer that does not overlap with the black matrices, so that difference in surface height of the color filter layer can be decreased. Not only flatness of the color filter substrate is improved, but also the problem that a color filter substrate has a larger chromatic aberration at different viewing angles can be ameliorated. Thus, the display effect of the display panel is promoted.

In some examples, the mask further includes:

a transmissive pattern corresponding to a portion of the color filter layer that does not overlap with the black matrices;

a light-blocking pattern corresponding to a portion of the black matrices that does not overlap with the color filter layer.

In some examples, the semi-transmissive pattern is made of chromium oxide. The thickness of a portion of the color filter layer that overlaps with the black matrices is determined by light transmittance of the semi-transmissive pattern, and so light transmittance of the semi-transmissive pattern can be adjusted according to the desired thickness of a portion of the color filter layer that overlaps with the black matrices.

According to an embodiment of the invention, there is further provided a manufacturing method of a color filter substrate, which includes:

a layer of color resin is formed on a substrate with black matrices formed thereon;

exposure is conducted on the color resin, so as to form pattern of a color filter layer, wherein, a thickness of a portion of the color filter layer that overlaps with the black matrices is smaller than a thickness of a portion of the color filter layer that does not overlap with the black matrices.

Regarding the color filter layer produced by the embodiment, the thickness of the portion of the color filter layer that overlaps with the black matrices is smaller than the thickness of the portion of the color filter layer that does not overlap with the black matrices, and thus difference in surface height of the color filter layer can be decreased. Not only flatness of the color filter substrate is improved, but also the problem that a color filter substrate has a larger chromatic aberration at different viewing angles can be ameliorated. Thus, the display effect of the display panel is promoted.

Further, the above method is to conduct exposure on the color resin with the above mask, thereby forming the color filter layer.

Hereinafter, the mask, the color filter substrate and manufacturing method thereof will be further introduced in combination with attached drawings.

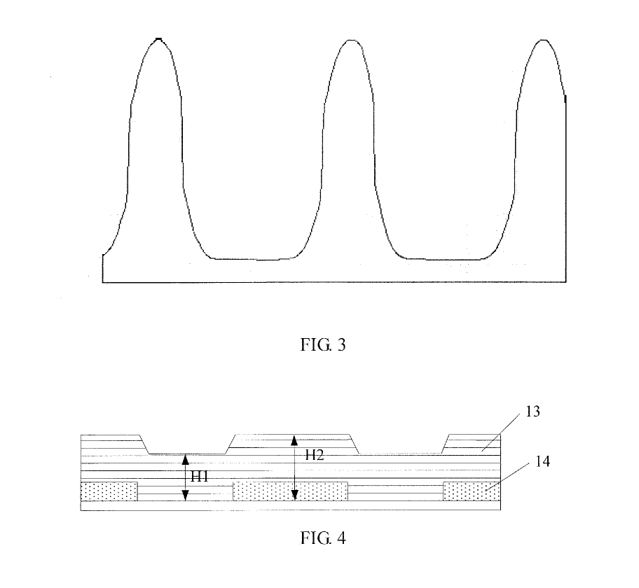

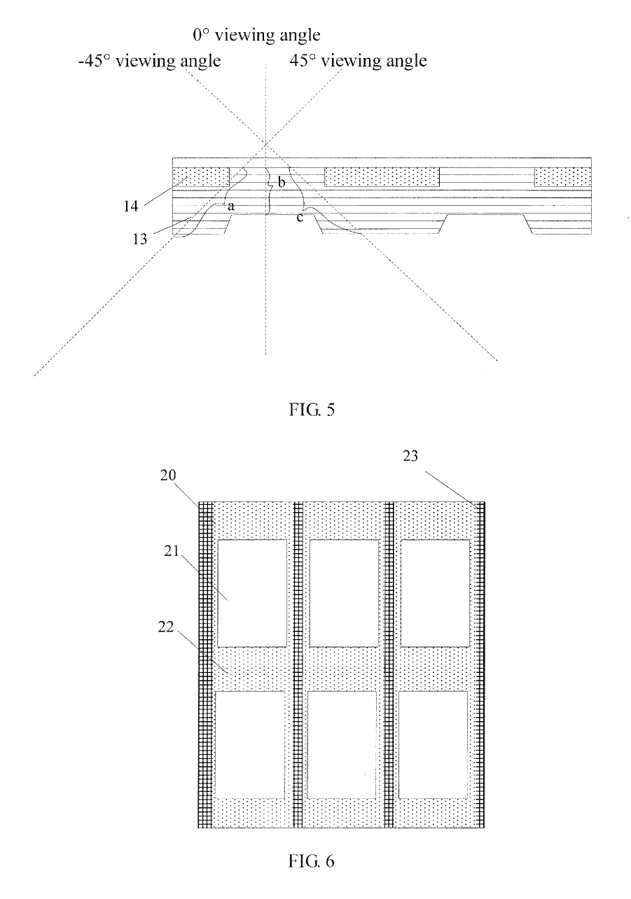

An existing mask useful for forming a color filter layer on a color filter substrate includes a transmissive pattern corresponding to a color filter layer and a light-blocking pattern except for the transmissive pattern, and the produced color filter layer has a portion that overlaps with black matrices. As illustrated in FIG. 4, a surface height H2 for a portion of a color filter layer 13 that overlaps with black matrices 14 and surface height H1 for a portion of the color filter layer 13 that does not overlap with the black matrices 14 have a difference with each other, and this affects flatness of the color filter substrate. Flatness of the color filter substrate may be improved by providing a planarizing layer on the color filter substrate, but as illustrated in FIG. 5, under the influence of surface height difference of the color filter layer, differences between a distance c that the line of sight propagates in the color filter layer 13 at a viewing angle of −45°, a distance b that the line of sight propagates in the color filter layer 13 at a viewing angle of 0°, and a distance a that the line of sight propagates in the color filter layer 13 at a viewing angle of 45° are bigger. This may cause the following problem: chromatic aberration of the color filter substrate at different viewing angles is larger. Eventually, the display effect of the display panel is affected.

As illustrated in FIG. 6, a mask 20 useful for forming a color filter layer on a color filer substrate according to the embodiment includes a semi-transmissive pattern 22 corresponding to a portion of the color filter layer that overlaps with black matrices, a transmissive pattern 21 corresponding to a portion of the color filter layer that does not overlap with the black matrices, and a light-blocking pattern 23 corresponding to a portion of the black matrices that does not overlap with the color filter layer. The light-blocking pattern 23 may be made of chromium, and the semi-transmissive pattern 22 may be made of chromium oxide. The thickness of a portion of the color filter layer that overlaps with the black matrices is determined by light transmittance of the semi-transmissive pattern 22, and so light transmittance of the semi-transmissive pattern can be adjusted according to the desired thickness of the portion of the color filter layer that overlaps with the black matrices. For example, the light transmittance of the semi-transmissive pattern 22 may be in the range of 50% to 70%.

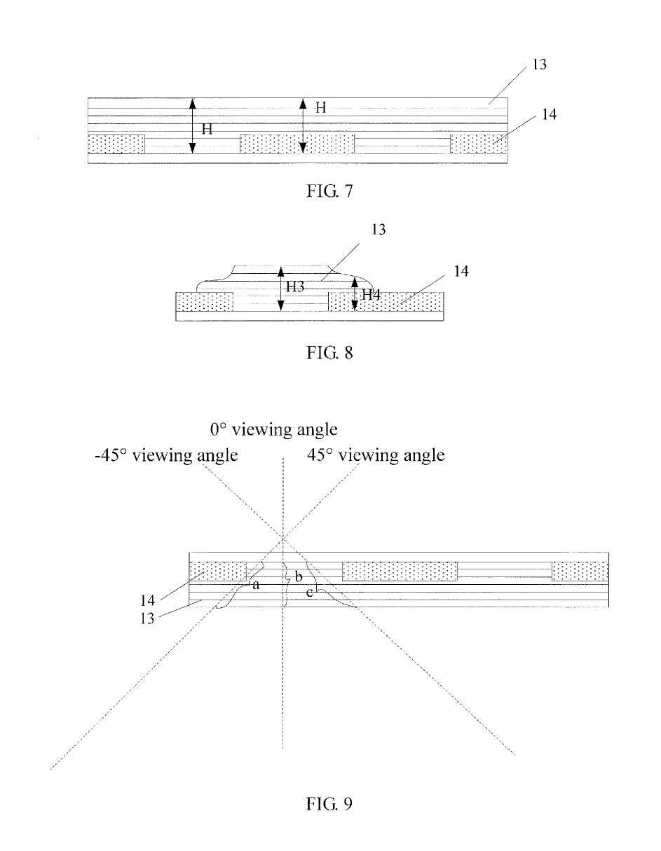

Upon formation of a color filter layer on a color filter substrate, a layer of color resin is coated on a substrate with black matrices formed thereon, and the color resin is subjected to exposure and development with the mask according to the embodiment. The color resin in a zone corresponding to the light-blocking pattern 23 is removed, the color resin in a zone corresponding to the semi-transmissive pattern 22 is partially retained, and the color resin in a zone corresponding to the transmissive pattern is fully retained, thereby forming the pattern of the color filter layer. As illustrated in FIG. 7, the thickness of the portion of a color filter layer 13 that overlaps with black matrices 14 is smaller than the thickness of a portion of the color filter layer 13 that does not overlap with the black matrices, and this ultimately makes each of the surface height for the portion of the color filter layer 13 that overlaps with the black matrices 14 and the surface height for the portion of the color filter layer 13 that does not overlap with the black matrices 14 be H. Thus, flatness of the color filter substrate is effectively enhanced. Alternatively, as illustrated in FIG. 8, the thickness of the portion of a color filter layer 13 that overlaps with black matrices 14 is smaller than the thickness of the portion of the color filter layer 13 that does not overlap with the black matrices, and this ultimately makes the difference between the surface height H4 for the portion of the color filter layer 13 that overlaps with the black matrices 14 and the surface height H3 for the portion of the color filter layer 13 that does not overlap with the black matrices 14 be smaller than the height (thickness, which is the size in a direction perpendicular to the substrate surface) of the black matrices 14.

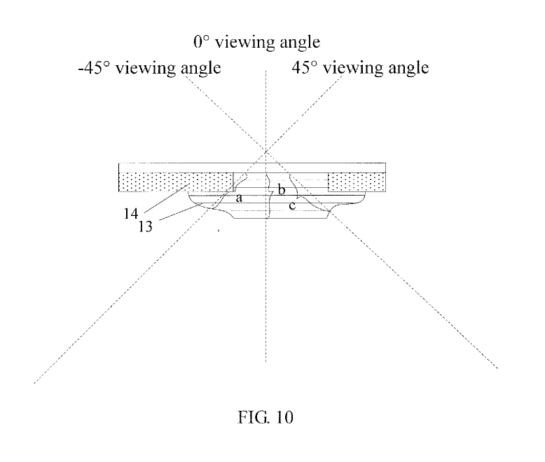

Additionally, as can be seen from FIG. 9 and FIG. 10, the differences between a distance c that the line of sight propagates in the color filter layer 13 at a viewing angle of −45°, a distance b that the line of sight propagates in the color filter layer 13 at a viewing angle of 0°, and a distance a that the line of sight propagates in the color filter layer 13 at a viewing angle of 45° are significantly reduced, so that a problem that the color filter substrate has a larger chromatic aberration at different viewing angles is ameliorated. Thus, the display effect of the display panel is promoted.

Descriptions made above are merely exemplary embodiments of the invention, but are not used to limit the protection scope of the invention. The protection scope of the invention is determined by attached claims.

This application claims the benefit of priority from Chinese patent application No. 201410687131.1, filed on Nov. 25, 2014, the disclosure of which is incorporated herein in its entirety by reference as a part of the present application.

1. A color filter substrate, comprising a base substrate, a black matrix and a color filter layer that are formed on the base substrate, wherein, the black matrix and the color filter layer are at least partially overlapped in a direction perpendicular to a surface of the base substrate, and a thickness of a portion of the color filter substrate that overlaps with the black matrix is smaller than a thickness of a portion of the color filter substrate that does not overlap with the black matrix.

2. The color filter substrate according to claim 1, wherein, in a location where the color filter layer and the black matrix overlap with each other, the black matrix is located between the color filter layer and the base substrate.

3. The color filter substrate according to claim 2, wherein, difference between a thickness sum of the color filter layer and the black matrix in the location where the color filter layer and the black matrix overlap and a thickness of the color filter layer in a location where the color filter layer and the black matrix do not overlap is not larger than a preset threshold.

4. The color filter substrate according to claim 3, wherein, the thickness sum of the color filter layer and the black matrix in the location where the color filter layer and the black matrix overlap is equal to the thickness of the color filter layer in the location where the color filter layer and the black matrix do not overlap.

5. The color filter substrate according to claim 3, wherein, the thickness sum of the color filter layer and the black matrix in the location where the color filter layer and the black matrix overlap is smaller than the thickness of the color filter layer in the location where the color filter layer and the black matrix do not overlap.

6. The color filter substrate according to claim 5, wherein, the difference between the thickness sum of the color filter layer and the black matrix in the location where the color filter layer and the black matrix overlap and the thickness of the color filter layer in the location where the color filter layer and the black matrix do not overlap is smaller than a thickness of the black matrix.

7. A display panel, comprising a color filter substrate, which includes a base substrate, a black matrix and a color filter substrate that are formed on the base substrate, wherein, the black matrix and the color filter layer are at least partially overlapped in a direction perpendicular to a surface of the base substrate, and a thickness of a portion of the color filter substrate that overlaps with the black matrix is smaller than a thickness of a portion of the color filter substrate that does not overlap with the black matrix.

8. The display panel according to claim 7, wherein, in a location where the color filter layer and the black matrix overlap with each other, the black matrix is located between the color filter layer and the base substrate.

9. The display panel according to claim 8, wherein, difference between a thickness sum of the color filter layer and the black matrix in the location where the color filter layer and the black matrix overlap and a thickness of the color filter layer in a location where the color filter layer and the black matrix do not overlap is not greater than a preset threshold.

10. The display panel according to claim 9, wherein, the thickness sum of the color filter layer and the black matrix in the location where the color filter layer and the black matrix overlap is equal to the thickness of the color filter layer in a location where the color filter layer and the black matrix do not overlap.

11. The display panel according to claim 9, wherein, the thickness sum of the color filter layer and the black matrix in the location where the color filter layer and the black matrix overlap is smaller than the thickness of the color filter layer in the location where the color filter layer and the black matrix do not overlap.

12. The display panel according to claim 11, wherein, the difference between the thickness sum of the color filter layer and the black matrix in the location where the color filter layer and the black matrix overlap and the thickness of the color filter layer in the location where the color filter layer and the black matrix do not overlap is smaller than a thickness of the black matrix.

13. A manufacturing method of a color filter substrate, comprising
forming a layer of color resin on a substrate with a black matrix formed thereon; and
performing exposure and development on the color resin, so as to form a pattern of a color filter layer, wherein, a thickness of the color filter layer that overlaps with the black matrix is smaller than a thickness of the color filter layer that does not overlap with the black matrix.

14. The method according to claim 13, wherein, in a location where the color filter layer and the black matrix overlap with each other, the black matrix is located between the color filter layer and the base substrate.

15. The method according to claim 14, wherein, difference between a thickness sum of the color filter layer and the black matrix in the location where the color filter layer and the black matrix overlap and a thickness of the color filter layer in a location where the color filter layer and the black matrix do not overlap is not larger than a preset threshold.

16. The method according to claim 15, wherein, the thickness sum of the color filter layer and the black matrix in the location where the color filter layer and the black matrix overlap is equal to the thickness of the color filter layer in the location where the color filter layer and the black matrix do not overlap.

17. The method according to claim 15, wherein, the thickness sum of the color filter layer and the black matrix in the location where the color filter layer and the black matrix overlap is smaller than the thickness of the color filter layer in a location where the color filter layer and the black matrix do not overlap.

18. The method according to claim 17, wherein, the difference between the thickness sum of the color filter layer and the black matrix in the location where the color filter layer and the black matrix overlap and the thickness of the color filter layer in the location where the color filter layer and the black matrix do not overlap is smaller than a thickness of the black matrix.
